(19) United States
(12) Patent Application Publication
(10) Pub. No.: US 2013/0147541 A1
(43) Pub. Date: Jun. 13, 2013

(54) CIRCUIT FOR CLEARING DATA STORED IN COMPLEMENTARY METAL-OXIDE-SEMICONDUCTOR

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD, Tu-Cheng (TW); HONG FU JIN PRECISION INDUSTRY (ShenZhen) CO., LTD, Shenzhen City (CN)

(21) Appl. No.: 13/598,821

(22) Filed: Aug. 30, 2012

(30) Foreign Application Priority Data
Dec. 13, 2011 (CN) 201110414474.7

(51) Int. Cl. H03K 17/687

(52) U.S. Cl. 327/437

(57) ABSTRACT

An exemplary circuit for clearing data stored in a complementary metal-oxide-semiconductor (CMOS) includes a power circuit and a button circuit. The power circuit supplies power for the CMOS. The button circuit is configured to clear data stored in the CMOS, and includes a switch and an electronic switch element. A first terminal of the switch is grounded, and a second terminal of the switch is coupled to a first terminal of the electronic switch element. A second terminal of the electronic switch element is grounded. A third terminal of the electronic switch element is coupled to the CMOS. When the switch is closed, the second terminal of the electronic switch element is connected to the third terminal of the electronic switch element, and the data stored in the CMOS is cleared.

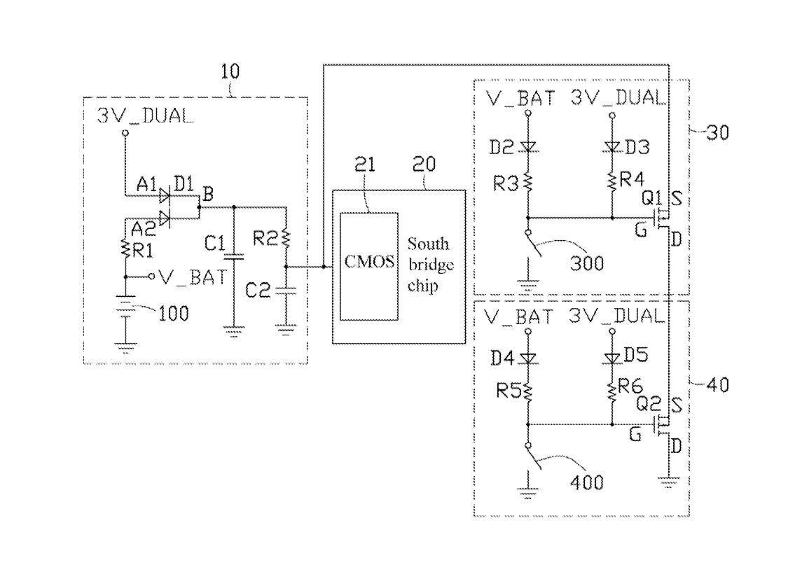

### BACKGROUND

1. Technical Field

The present disclosure relates to a circuit for clearing data stored in a complementary metal-oxide-semiconductor (CMOS).

2. Description of Related Art

Currently, a typical electrical jumper includes a base having a plurality of pins, and a jumper block. The jumper can be employed to clear data stored in a CMOS of a computer, by using the jumper block to connect to corresponding pins of the plurality of pins. When the computer is operating abnormally, the user has to open the chassis of the computer, and then connect the corresponding pins with the jumper block. This is inconvenient and time consuming.

Therefore, there is room for improvement in the art.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the present disclosure. Moreover, in the drawing, like reference numerals designate corresponding parts.

The drawing is a schematic diagram of an embodiment of a circuit for clearing data stored in a complementary metal-oxide-semiconductor (CMOS), according to the present disclosure.

### DETAILED DESCRIPTION

The drawing illustrates an embodiment of a circuit used for clearing data stored in a complementary metal-oxide-semiconductor (CMOS) 21. Typically, the CMOS 21 is part of a chip, such as a south bridge chip 20. The circuit includes a power circuit 10, a first button circuit 30, and a second button circuit 40.

The power circuit 10 includes a Schottky diode D1, two capacitors C1 and C2, two resistors R1 and R2, and a battery 100. A first anode A1 of the Schottky diode D1 is coupled to a power terminal 3V_DUAL, and a second anode A2 of the Schottky diode D1 is coupled to a positive of the battery 100 through the resistor R1. A negative of the battery 100 is grounded. A cathode of the Schottky diode D1 is grounded through the resistor R2 and the capacitor C2 in that order, and is also grounded through the capacitor C1. A node between the resistor R2 and the capacitor C2 is coupled to the CMOS 21.

If the power circuit 10 is connected to an external power source, the external power source supplies power for the south bridge chip 20, via the power terminal 3V_DUAL, the Schottky diode D1 and the resistor R2 in that order. If the power circuit 10 is disconnected from the external power source, the battery 100 supplies power for the south bridge chip 20, via the resistor R1, the Schottky diode D1, and the resistor R2 in that order.

The first button circuit 30 includes two diodes D2 and D3, two resistors R3 and R4, a field effect transistor (FET) Q1, and a first switch 300. In the embodiment, the first switch 300 is controlled by a mechanical button, such as a reset button, arranged on a front panel of a chassis encasing the above-mentioned elements. A first terminal of the first switch 300 is grounded. A second terminal of the first switch 300 is coupled to a cathode of the diode D2 through the resistor R3, and coupled to a cathode of the diode D3 through the resistor R4. The second terminal of the first switch 300 is also coupled to a gate of the FET Q1. An anode of the diode D2 is coupled to the positive of the battery 100. An anode of the diode D3 is coupled to the power terminal 3V_DUAL. A source of the FET Q1 is coupled to the node between the resistor R2 and the capacitor C2. In the embodiment, the FET Q1 is a p-channel FET.

The second button circuit 40 includes two diodes D4 and D5, two resistors R5 and R6, an FET Q2, and a second switch 400. In the embodiment, the second switch 400 is controlled by a mechanical button, such as a power button, arranged on the front panel of the chassis. A first terminal of the second switch 400 is grounded. A second terminal of the second switch 400 is coupled to a cathode of the diode D4 through the resistor R5, and coupled to a cathode of the diode D5 through the resistor R6. The second terminal of the second button 400 is also coupled to a gate of the FET Q2. An anode of the diode D4 is coupled to the positive of the battery 100. An anode of the diode D5 is coupled to the power terminal 3V_DUAL. A drain of the FET Q2 is grounded. A source of the FET Q2 is coupled to a drain of the FET Q1. In the embodiment, the FET Q2 is a p-channel FET.

According to the working principle of the south bridge chip 20, the data stored in the south bridge chip 20 is cleared when a level of the voltage of a pin coupled to the source of the FET Q1 is low, such as logic 0.

To clear the data stored in the south bridge chip 20, the first switch 300 and the second switch 400 are closed at the same time. Thereby, the gates of the FETs Q1 and Q2 are grounded, and the FETs Q1 and Q2 are turned on. Thus the voltage level of the drain of the FET Q1 goes low. Accordingly, the voltage level of the source of the FET Q1 goes low, whereby the source of the FET Q1 outputs a low level signal to the south bridge chip 20, and the data stored in the south bridge chip 20 is cleared.

In other embodiments, the first button circuit 30 may be omitted to save on costs, and in such cases the source of the FET Q2 is coupled directly to the south bridge chip 20. With this configuration, the data stored in the south bridge chip 20 is cleared when the second switch 400 is closed.

As described above, the FETs Q1 and Q2 just function as electronic switch elements. Consequently, the FETs Q1 and Q2 may be replaced by other types of electronic switch elements, such as transistors. For instance, the FETs Q1 and Q2 can be replaced by two positive-negative-positive bipolar junction transistors (PNP-BJTs). Bases, emitters, and collectors of the PNP-BJTs respectively correspond to the gates, sources, and drains of the FETs Q1 and Q2.

While preferred and exemplary embodiments have been described by way of example, it is to be understood that the disclosure is not limited thereto. To the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A circuit for clearing data stored in a complementary metal-oxide-semiconductor (CMOS), comprising:
a power circuit supplying power for the CMOS; and
a button circuit comprising a first diode, a first resistor, a first electronic switch element, and a switch;
wherein a first terminal of the switch is grounded, a second terminal of the switch is coupled to a cathode of the first diode through the first resistor, and coupled to a first terminal of the first electronic switch element, an anode of the first diode is coupled to the power circuit, a second terminal of the first electronic switch element is grounded, and a third terminal of the first electronic switch element is coupled to the CMOS; and
wherein the second terminal of the first electronic switch element is connected to the third terminal of the first electronic switch element in response to a voltage level of the first terminal of the first electronic switch element being low, and the second terminal of the first electronic switch element is disconnected from the third terminal of the first electronic switch element in response to the voltage level of the first terminal of the first electronic switch element being high.

2. The circuit of claim 1, wherein the power circuit comprises a battery, a second diode, a second resistor, and a first capacitor, a negative of the battery is grounded, a positive of the battery is coupled to an anode of the second diode, a cathode of the second diode is grounded through the second resistor and the first capacitor in that order, the anode of the first diode is coupled to the positive of the battery, and a node between the second resistor and the first capacitor is coupled to the CMOS.

3. The circuit of claim 2, wherein the second diode is a Schottky diode, the power circuit further comprises a power terminal, the button circuit further comprises a third diode and a third resistor, a cathode of the third diode is coupled to the first terminal of the first electronic switch element through the third resistor, an anode of the third diode is coupled to the power terminal, and the other anode of the Schottky diode is coupled to the power terminal.

4. The circuit of claim 3, wherein the power circuit further comprises a fourth resistor, and the positive of the battery is coupled to the anode of the Schottky diode through the fourth resistor.

5. The circuit of claim 3, wherein the power circuit further comprises a second capacitor connected between the cathode of the Schottky diode and ground.

6. The circuit of claim 1, wherein the first electronic switch element is a p-channel field effect transistor, and a gate, a drain, and a source of the p-channel field effect transistor respectively correspond to the first terminal, the second terminal, and the third terminal of the first electronic switch element.

7. A circuit for clearing data stored in a complementary metal-oxide-semiconductor (CMOS), comprising:
a power circuit supplying power for the CMOS;
a first button circuit comprising a first diode, a first resistor, a first electronic switch element, and a first switch; and
a second button circuit comprising a second diode, a second resistor, a second electronic switch element, and a second switch;
wherein the first electronic switch element comprises a first terminal, a second terminal, and a third terminal, a first terminal of the first switch is grounded, a second terminal of the first switch is coupled to a cathode of the first diode through the first resistor, and coupled to the first terminal of the first electronic switch element, an anode of the first diode is coupled to the power circuit, and the second terminal of the first electronic switch element is grounded;
wherein the second terminal of the first electronic switch element is connected to the third terminal of the first electronic switch element in response to a voltage level of the first terminal of the first electronic switch element being low, and the second terminal of the first electronic switch element is disconnected from the third terminal of the first electronic switch element in response to the voltage level of the first terminal of the first electronic switch element being high;
wherein a first terminal of the second switch is grounded, a second terminal of the second switch is coupled to a cathode of the second diode through the second resistor, and coupled to a first terminal of the second electronic switch element, an anode of the second diode is coupled to the power circuit, a second terminal of the second electronic switch element is coupled to the third terminal of the first electronic switch element, and a third terminal of the second electronic switch element is coupled to the CMOS; and
wherein the second terminal of the second electronic switch element is connected to the third terminal of the second electronic switch element in response to a voltage level of the first terminal of the second electronic switch element being low, and the second terminal of the second electronic switch element is disconnected from the third terminal of the second electronic switch element in response to the voltage level of the first terminal of the second electronic switch element being high.

8. The circuit of claim 7, wherein the power circuit comprises a battery, a third diode, a third resistor, and a first capacitor, a negative of the battery is grounded, a positive of the battery is coupled to an anode of the third diode, a cathode of the third diode is grounded through the third resistor and the first capacitor in that order, the anodes of the first diode and the second diode are coupled to the positive of the battery, and a node between the third resistor and the first capacitor is coupled to the CMOS.

9. The circuit of claim 8, wherein the third diode is a Schottky diode, the power circuit further comprises a power terminal, the first button circuit further comprises a fourth diode and a fourth resistor, a cathode of the fourth diode is coupled to the first terminal of the first electronic switch element through the fourth resistor, an anode of the fourth diode is coupled to the power terminal, the other anode of the Schottky diode is coupled to the power terminal, the second button circuit further comprises a fifth diode and a fifth resistor, a cathode of the fifth diode is coupled to the first terminal of the second electronic switch element through the fifth resistor, and an anode of the fifth diode is coupled to the power terminal.

10. The circuit of claim 9, wherein the power circuit further comprises a sixth resistor, and the positive of the battery is coupled to the anode of the Schottky diode through the sixth resistor.

11. The circuit of claim 9, wherein the power circuit further comprises a second capacitor connected between the cathode of the Schottky diode and ground.

12. The circuit of claim 7, wherein the first and second electronic switch elements are p-channel field effect transistors, and gates, drains, and sources of the p-channel field effect transistors respectively correspond to the first terminals, the second terminals, and the third terminals of the first and second electronic switch elements.
